(19) United States
(12) Patent Application Publication
(10) Pub. No.: US 2024/0222448 A1
(43) Pub. Date: Jul. 4, 2024

(54) MIDDLE OF THE LINE ARCHITECTURE WITH SUBTRACTIVE SOURCE/DRAIN CONTACT

(71) Applicant: International Business Machines Corporation, Armonk, NY (US)

(72) Inventors: Eric Miller, Albany, NY (US); Nelson Felix, Slingerlands, NY (US); Andrew Herbert Simon, FISHKILL, NY (US)

(21) Appl. No.: 18/148,577

(22) Filed: Dec. 30, 2022

(51) Int. Cl. H01L 29/417; H01L 21/768; H01L 21/8234; H01L 29/06; H01L 29/423; H01L 29/66; H01L 29/775; H01L 29/786

(52) U.S. Cl. CPC H01L 29/41733; H01L 21/76831; H01L 21/823412; H01L 21/823418; H01L 29/0673; H01L 29/42392; H01L 29/66439; H01L 29/775; H01L 29/78696

(57) ABSTRACT

A semiconductor device includes first and second nanosheet stacks above an upper surface of a semiconductor substrate, a first source/drain on an end of the first nanosheet stack, and a second source/drain on an end of the second nanosheet stack. A first gate stack wraps around individual channels of the first nanosheet stack and a second gate stack wraps around individual channels the second nanosheet stack. An interlayer dielectric covers the first and second nanosheet stacks, the first and second source/drains, and the first and second gate stacks. The semiconductor device further includes a first source/drain contact that contacts the first source/drain and a second source/drain contact that contacts the second source/drain. The first and second source/drain contacts extend continuously from the first and second source/drains, respectively, to an upper surface of the interlayer dielectric.

### BACKGROUND

The present invention generally relates to fabrication methods and resulting structures for semiconductor devices, and more specifically, to a middle of the line architecture implementing a subtractive source/drain contact.

With the current trends in integrated circuit (IC) miniaturization, and increasingly smaller critical dimensions, it is desirable in semiconductor device technology to integrate many different functions on a single chip. In the IC chip fabrication industry, there are three sections referred to in a typical IC chip build: front end of the line (FEOL), back end of the line (BEOL), and the section that connects those two together, which is referred to as the middle of the line (MOL). The FEOL is made up of semiconductor devices, e.g., transistors, the BEOL is made up of interconnects and wiring, and the MOL includes one or more interconnects between the FEOL and BEOL, along with material to prevent the diffusion of BEOL metals to FEOL devices.

The FEOL transistor devices are typically processed using single crystal and poly-crystalline silicon. The BEOL connections are typically made of multiple metals; the bulk of the conductor is copper. If copper diffuses into the FEOL silicon-based devices, it can cause shorting or alter sensitive transistor characteristics and render the semiconductor useless. The MOL connection is therefore implemented to prevent the diffusion of copper into the FEOL.

### SUMMARY

According to a non-limiting embodiment of the invention, a semiconductor device includes first and second nanosheet stacks above a semiconductor substrate, a first source/drain on an end of the first nanosheet stack, and a second source/drain on an end of the second nanosheet stack. A first gate stack wraps around individual channels of the first nanosheet stack and a second gate stack wraps around individual channels of the second nanosheet stack. The semiconductor device further includes an interlayer dielectric (ILD), a first source/drain contact, and a second source contact. The ILD covers the first and second nanosheet stacks, the first and second source/drains, and the first and second gate stacks. The first source/drain contact contacts the first source/drain and the second source/drain contacts the second source/drain. Each of the first and second source/drain contacts extends continuously from the first and second source/drains, respectively, to an upper surface of the ILD.

Embodiments of the invention are also directed to a semiconductor device that includes a nanosheet stack between a first source/drain and a second source/drain, a gate stack that wraps around individual channels of the nanosheet stack, and an interlayer dielectric (ILD) that covers the nanosheet stack, the first and second source/drains, and the gate stack. The semiconductor device further includes a source/drain contact, a recessed source/drain contact, and an isolation element. The source/drain contact extends continuously from an upper surface of the first source/drain to an upper surface of the ILD. The recessed source/drain contact is on an upper surface of the second source/drain. The isolation element separates the recessed source/drain contact from the upper surface of the ILD.

According to another non-limiting embodiment of the invention, a method is provided for fabricating a semiconductor device The method includes forming a plurality of nanosheet stacks above an upper surface of a semiconductor substrate, forming a plurality of source/drains, and forming a plurality of gate stacks. Each of the source/drains are formed on an end of a respective nanosheet stack among the plurality of nanosheet stacks, and each of the gate stacks wrap around individual channels of a respective nanosheet stack among the plurality of nanosheet stacks. The method further includes depositing an interlayer dielectric (ILD) on the semiconductor substrate that covers the plurality of nanosheet stacks, the plurality of source/drains, and the plurality of gate stacks. The method further includes forming a plurality of source/drain contacts that contact the plurality of source/drains. Each of the source/drain contacts extending continuously from the plurality of source/drains to an upper surface of the ILD. The method further includes recessing at least one of target source/drain contact among the plurality of source/drain contacts without recessing one or more remaining source/drain contacts among the plurality of source/drain contacts to form at least one ILD trench in the ILD. The method further includes depositing a dielectric material in the at least one ILD trench to form at least one isolation element that separates the at least one target source/drain contact from the upper surface of the ILD.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a top-down view of a semiconductor device including different regions designated for various fabrications processes;

FIG. 1B is a cross-sectional view of the semiconductor device shown in FIG. 1A taken along line 1-1 following a source/drain contact etch;

FIG. 1C is a cross-sectional view of the semiconductor device shown in FIG. 1A taken along line 2-2 following the source/drain contact etch;

FIG. 1D is a cross-sectional view of the semiconductor device shown in FIG. 1A taken along line 3-3 following the source/drain contact etch;

FIG. 1E is a cross-sectional view of the semiconductor device shown in FIG. 1A taken along line 4-4 following the source/drain contact etch;

FIG. 2A is a cross-sectional view of the semiconductor device shown in FIG. 1A taken along line 1-1 following a source/drain contact formation process to form source/drain contacts on an upper surface of respective source/drains;

FIG. 2B is a cross-sectional view of the semiconductor device shown in FIG. 1A taken along line 2-2 following the source/drain contact formation process;

FIG. 2C is a cross-sectional view of the semiconductor device shown in FIG. 1A taken along line 3-3 following the source/drain contact formation process;

FIG. 2D is a cross-sectional view of the semiconductor device shown in FIG. 1A taken along line 4-4 following the source/drain contact formation process;

FIG. 3A is a cross-sectional view of the semiconductor device shown in FIG. 1A taken along line 1-1 following a source/drain contact mask patterning process;

FIG. 3B is a cross-sectional view of the semiconductor device shown in FIG. 1A taken along line 2-2 following the source/drain contact mask patterning process;

FIG. 3C is a cross-sectional view of the semiconductor device shown in FIG. 1A taken along line 3-3 following the source/drain contact mask patterning process;

FIG. 3D is a cross-sectional view of the semiconductor device shown in FIG. 1A taken along line 4-4 following the source/drain contact mask patterning process;

FIG. 4A is a cross-sectional view of the semiconductor device shown in FIG. 1A taken along line 1-1 following a subtractive etch process to partially recess targeted source/drain contacts;

FIG. 4B is a cross-sectional view of the semiconductor device shown in FIG. 1A taken along line 2-2 following the subtractive etch process;

FIG. 4C is a cross-sectional view of the semiconductor device shown in FIG. 1A taken along line 3-3 following the subtractive etch process;

FIG. 4D is a cross-sectional view of the semiconductor device shown in FIG. 1A taken along line 4-4 following the subtractive etch process;

FIG. 5A is a cross-sectional view of the semiconductor device shown in FIG. 1A taken along line 1-1 after performing a dielectric deposition process to form isolation elements on the targeted source/drains;

FIG. 5B is a cross-sectional view of the semiconductor device shown in FIG. 1A taken along line 2-2 following the dielectric deposition process;

FIG. 5C is a cross-sectional view of the semiconductor device shown in FIG. 1A taken along line 3-3 following the dielectric deposition process;

FIG. 5D is a cross-sectional view of the semiconductor device shown in FIG. 1A taken along line 4-4 following the dielectric deposition process;

FIG. 6A is a cross-sectional view of the semiconductor device shown in FIG. 1A taken along line 1-1 following a gate contact mask patterning process;

FIG. 6B is a cross-sectional view of the semiconductor device shown in FIG. 1A taken along line 2-2 following the gate contact mask patterning process;

FIG. 6C is a cross-sectional view of the semiconductor device shown in FIG. 1A taken along line 3-3 following the gate contact mask patterning process;

FIG. 6D is a cross-sectional view of the semiconductor device shown in FIG. 1A taken along line 4-4 following the gate contact mask patterning process;

FIG. 7A is a cross-sectional view of the semiconductor device shown in FIG. 1A taken along line 1-1 following a gate contact reactive ion etch process to form a gate contact trench that exposes an underlying gate contact;

FIG. 7B is a cross-sectional view of the semiconductor device shown in FIG. 1A taken along line 2-2 following the gate contact reactive ion etch process;

FIG. 7C is a cross-sectional view of the semiconductor device shown in FIG. 1A taken along line 3-3 following the gate contact reactive ion etch process;

FIG. 7D is a cross-sectional view of the semiconductor device shown in FIG. 1A taken along line 4-4 following the gate contact reactive ion etch process;

FIG. 8A is a cross-sectional view of the semiconductor device shown in FIG. 1A taken along line 1-1 following a gate contact formation process to form a gate contact on a respective gate stack;

FIG. 8B is a cross-sectional view of the semiconductor device shown in FIG. 1A taken along line 2-2 following the gate contact formation process;

FIG. 8C is a cross-sectional view of the semiconductor device shown in FIG. 1A taken along line 3-3 following the gate contact formation process; and

FIG. 8D is a cross-sectional view of the semiconductor device shown in FIG. 1A taken along line 4-4 following the gate contact formation process.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, MOL contacts are contacts that connect transistor devices such as field effect transistors (FETs) to the BEOL metal levels. These MOL contacts include at least one gate contact and source/drain contacts. The gate contact extends vertically through an interlayer dielectric (ILD) material from a metal wire or via in the first BEOL metal level (referred to herein as the Mo level) to the gate stack of the FET. Each source/drain contact extends vertically through the ILD material from a metal wire or via in the first BEOL metal level to a metal plug, which is above and immediately adjacent to a source/drain region of the FET.

Conventional fabrication techniques typically perform a damascene process to form the MOL source/drain contact. The damascene process, however, requires several mask layers along with several sequential etching processes that forms a multi-layered MOL source/drain contact. The need to perform several sequential etching processes prevents the source/drain contact and the gate contact from sharing the same metal layer (e.g., the M1 track). Therefore, additional masks are often incorporated into the fabrication process to form a separate “jumper” connection to connect the source/drain contact and the gate contact. The multi-layered MOL source/drain contact also defines an interface between the lower layer MOL source/drain contact and the upper layer MOL source/drain contact, which increases the overall contact resistance.

Turning now to an overview of aspects of the present invention, one or more embodiments of the invention address the above-described shortcomings by providing fabrication method that implements a subtractive etch process to facilitate formation of a source/drain contact having a single continuous body (i.e., a single layer) that excludes any interface between the contact bottom end and the contact upper end. The fabrication process described herein also provides a structure and method for forming a semiconductor device that includes a source/drain contact formed from a first electrically conductive material and a gate contact via formed from either same first electrically conductive of the source/drain contact or a second electrically conductive material different from the first electrically conductive material used form the source/drain contact.

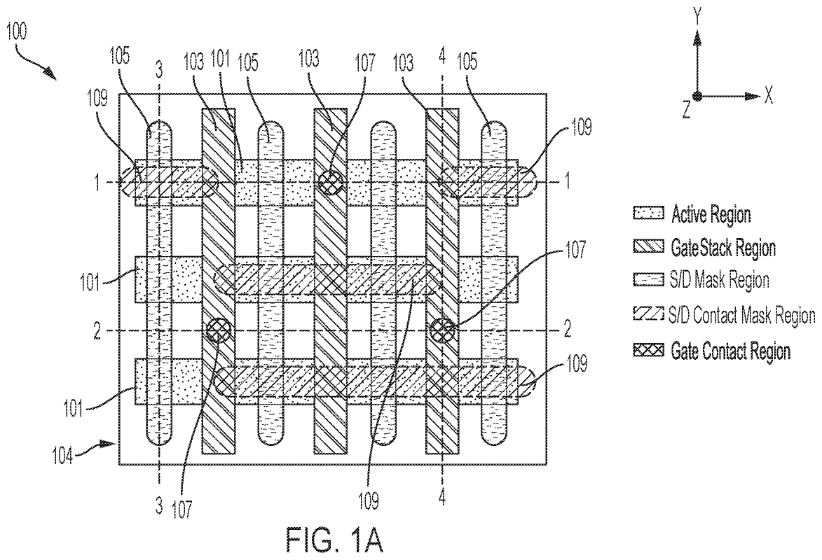

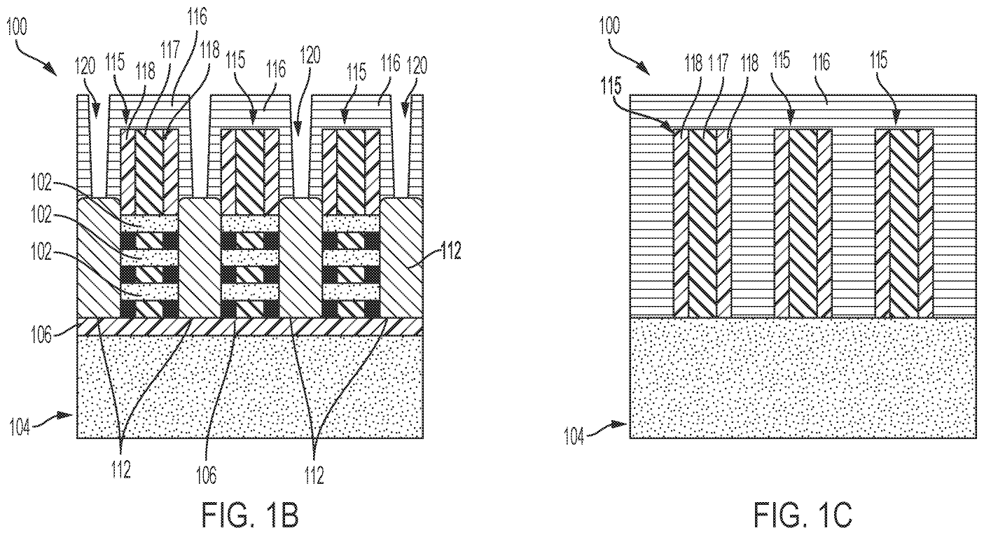

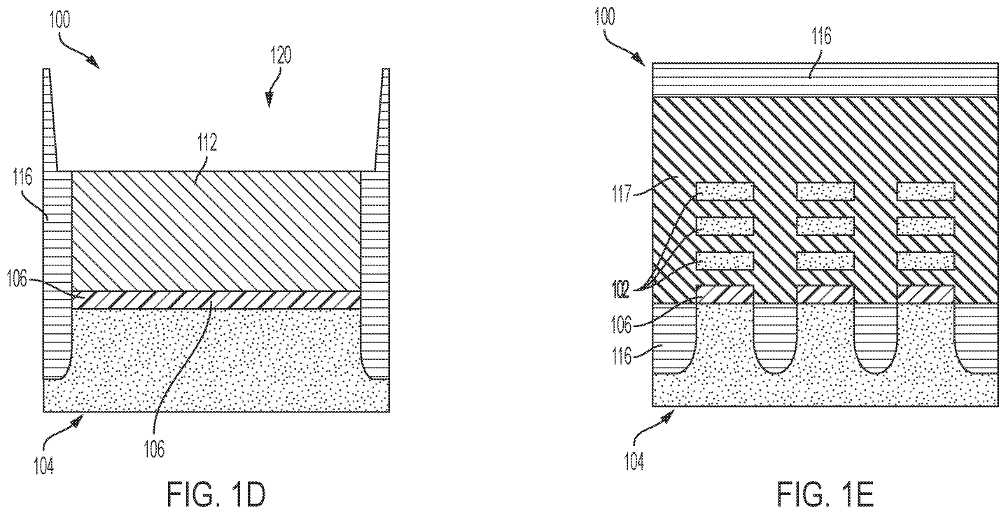

Turning now to a more detailed description of fabrication operations and resulting structures according to various non-limiting embodiments of the invention, FIG. 1A depicts a top-down view of a semiconductor device 100 at an intermediate fabrication stage following various semiconductor fabrication processes.

FIG. 1A also illustrates various regions designated to receive or support a particular semiconductor component or fabrication element. According to one or more non-limiting embodiments, the semiconductor device 100 includes one or more active regions 101 to be formed on a substrate 104, and one or more gate stack regions 103 extending perpendicularly across the active regions 101. The active regions 101 are designated for fabrication of respective channels (e.g., nanosheets) of the semiconductor device 100, and the gate stack regions 103 are designated for fabrication of respective gate stacks of the semiconductor device 100. The semiconductor device 100 further includes one or more source/drain mask regions 105, one or more gate contact regions 107, and one or more source/drain contact mask regions 109. The source/drain mask regions 105 are designated to receive mask layers (e.g., a source/drain mask layer) used to fabricate respective source/drains of the semiconductor device 100. The source/drain contact mask regions 109 are designated to receive mask layers (e.g., a source/drain contact mask layer) used to fabricate respective source/drain contacts, for establishing electrical conductivity with one or more source/drains of the semiconductor device 100. The gate contact regions 107 are designated to receive a gate contact for establishing electrical conductivity with a respective gate stack formed in the gate stack regions 103 of the semiconductor device 100.

FIGS. 1B-1E depict various cross-sectional views of the semiconductor device 100 illustrated in FIG. 1A. As described herein, an intermediate fabrication stage or intermediate semiconductor device is defined as a semiconductor device in a stage of fabrication prior to a final stage. For example, FIG. 1B is a cross-section of the semiconductor device 100 taken across line 1-1 following a source/drain contact etch. FIG. 1C is a cross-section of the semiconductor device 100 taken across line 2-2, which depicts gate stacks 115 formed in the gate stack regions 103 following the source/drain contact etch. FIG. 1D is a cross-section of the semiconductor device 100 taken along line 3-3, which depicts source/drains 112 following the source/drain contact etch. FIG. 1E is a cross-section of the semiconductor device 100 taken along line 4-4, which depicts a gate electrode 117 formed in the gate stack regions 103 and wrapping around nanosheets 102 formed in the active channel region 101.

As shown in FIGS. 1B-1E, the semiconductor device 100 includes a plurality of nanosheets 102. The nanosheets 102 are formed over the substrate 104 and in the active regions 101 to serve as the active channel(s) of the semiconductor device 100. For case of discussion, reference is made to operations performed on and to nanosheet stacks (e.g., a stack arrangement of the nanosheets 102) having multiple nanosheets (e.g. three nanosheets). It is understood, however, that each nanosheet stack can include any number of nanosheets 102. For example, nanosheet stacks can include two nanosheets 102, five nanosheets 102, eight nanosheets 102, thirty nanosheets 102 (e.g., 3D NAND), or any number of nanosheets 102. Moreover, it is not necessary that each nanosheet stack have a same number of nanosheets 102, and other configurations having any distribution of nanosheets 102 is within the contemplated scope of this disclosure.

The nanosheets 102 and the substrate 104 can be made of any suitable semiconductor material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlInAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys. The nanosheets 102 and the substrate 104 can be made of the same, or different, semiconductor materials. In some embodiments, the nanosheets 102 have a thickness of about 5 nm to about 15 nm, for example 10 nm, although other thicknesses are within the contemplated scope of this disclosure. In some embodiments, the substrate 104 and include a bottom isolation layer 106 formed on the substrate upper surface. The bottom isolation layer 106 can be made of any suitable dielectric material, such as, for example, silicon oxide, silicon nitride, SiON, SiC, SiOCN, and SiBCN.

With further references to FIGS. 1B-1E, FEOL fabrication processes can be performed to form source/drains 112, a gate stack 115, and an interlayer dielectric (ILD) 116. In some embodiments, the source/drains 112 are epitaxially grown or otherwise formed from exposed sidewalls of the nanosheets 102. In some embodiments, the source/drains 112 are made from different epitaxial materials. In some embodiments, the source/drains 112 include dopants such as n-type dopants or p-type dopants. In some examples, a first source drain 112 can include n-type dopants while an opposing source/drain 112 can include p-type dopants allowing for complementary transistor architectures (e.g., CMOS). For example, the first source/drain 112 can include InGaAs having n-type dopants (e.g., P, As, Sb, etc.) and the second source/drain 112 include GaAsSb having p-type dopants (e.g., B, In, etc.). It should be appreciated that a particular arrangement of P-type and N-type devices is not meant to be particularly limited. Other configurations (e.g., P-TFET, N-TFET, P-TFET, all N-TFET, all P-TFET, etc.) are within the contemplated scope of this disclosure and can be achieved using the processes described herein.

The ILD 116 is deposited or otherwise formed on the source/drains 112 and the gate stacks 115. The ILD 116 can be made of any suitable dielectric material, such as, for example, oxides, a low-k dielectric, nitrides, silicon nitride, silicon oxide, SiON, SiC, SiOCN, and SiBCN.

The gate stack 115 includes a gate electrode 117, and gate spacers 118 formed on sidewalls of the gate electrode 117. The gate spacers 118 can be made of any suitable dielectric material, such as, for example, silicon oxide, silicon nitride, silicon carbide, hydrogenated silicon carbonitrides, silicon oxynitrides, and silicon borocarbonitrides, although other dielectrics are within the contemplated scope of this disclosure. In some embodiments, spacer material is deposited using a chemical vapor deposition (CVD) process, and patterned using an anisotropic etch, for example, a reactive ion etch (RIE). In one or more non-limiting embodiments of the invention, the gate stack 115 can be formed as a gate-all-around gate stack (also referred to as a “wrap-around gate stack”, which wraps around the individual channels defined by the nanosheets 102 included in the nanosheet stack.

In some embodiments, sacrificial layers (not separately shown) formed on and below the nanosheets 102 and are recessed to form the inner spacers (not shown) are formed in the recess. In some embodiments, the sacrificial layers are recessed to the nanosheets 102. The inner spacers can be made of any suitable dielectric material, such as, for example, silicon oxide, silicon nitride, SiON, SiC, SiOCN, and SiBCN.

With continued reference to FIGS. 1A and 1D, the ILD 116 is illustrated following a lithography patterning process. The lithography patterning process involves various masking, patterning and etching processes that are well-known to one of ordinary skill in the art. In one or more non-limiting embodiments, the lithography patterning process includes depositing a mask material (not shown) on an upper surface of the ILD 116, patterning the mask material to form mask elements (not shown) that cover the gate stacks 115 and define openings exposing portions of the ILD 116, and etching the exposed portions of the ILD 116 while preserving the ILD 116 and gate stacks 115 covered by the mask elements. Accordingly, the pattern is transferred into the ILD 116 to form source/drain contact trenches 120 that expose an upper surface of the source/drains 112.

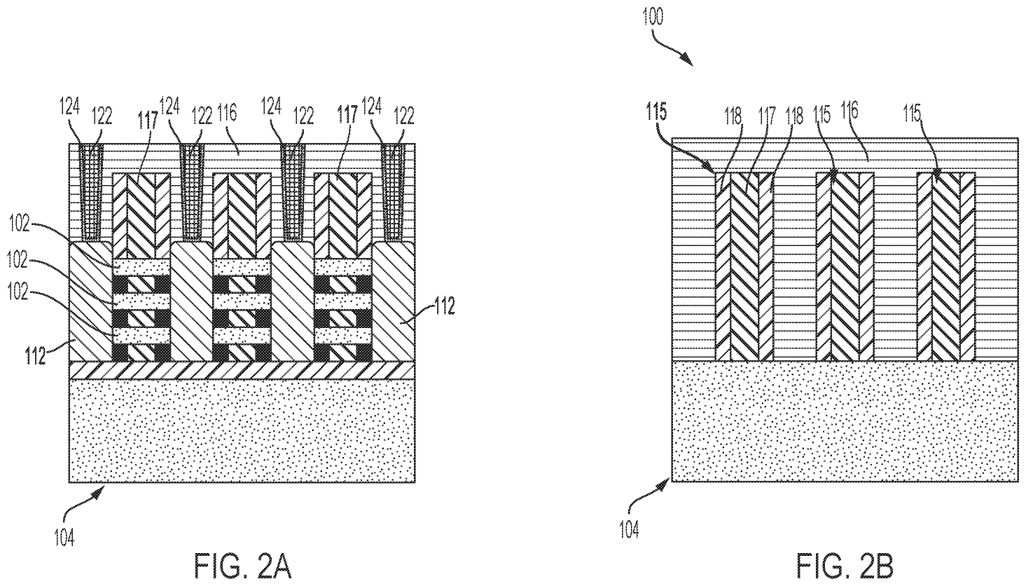

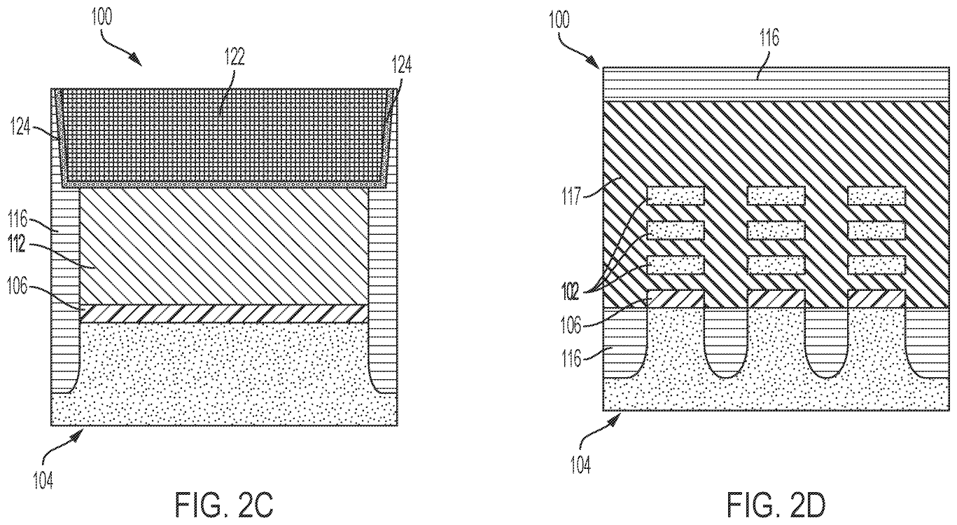

Turning now to FIGS. 2A-2D, the semiconductor device 100 is illustrated in various cross-sectional views following a source/drain contact formation process. The source/drain contact formation process involves depositing an electrically conductive material (e.g., a metal material) in the source/drain contact trenches 120 and planarizing the upper surface of the ILD 116. The source/drain electrically conductive material can include, but is not limited to, copper (Cu), tungsten (W), molybdenum (Mo), ruthenium (Ru), rhodium (Rh), iridium (Ir). A chemical-mechanical planarization (CMP) process, for example, can be performed to planarize the ILD upper surface. As a result, the source/drain contact formation process forms source/drain contacts 122 embedded in the ILD 116. The source/drain contacts 122 have a body that extends continuously from a bottom end that contacts a respective source/drain 112 to an upper end that is co-planar, or substantially co-planar, with the upper surface of the ILD 116.

Accordingly, semiconductor device 100 described according to various non-limiting embodiments of the invention provides a single layer, continuous contact that can be utilized as a source/drain contact integrated with a source/drain via. In other words, multiple conductive layers (e.g., a separate source/drain via) are not required to establish a connection with the source/drain contact formed on the source/drain and a separate metal layer. In this manner, the additional masks and pattering processes found in the prior art can be eliminated. In addition, the source/drain contacts 122 extend continuously from the via bottom surface to the via upper surface and can be formed using a single electrically conductive material so as to avoid forming an interface between the bottom surface and the upper surface. Accordingly, the source/drain contact resistance is reduced compared to the conventional multi-layer source/drain contact architectures, for example, found in the prior art.

With continued reference to FIGS. 2A and 2C, the source/drain contact formation process can involve performing a conformal deposition process to form a contact liner 124 on the sidewalls and the base of the source/drain contact trenches 120 prior to depositing the electrically conductive material used to form the source/drain contacts 122. The material used to form the liner 124 can include, but is not limited to, titanium nitride (TiN), tantalum nitride (TaN), and tungsten (W).

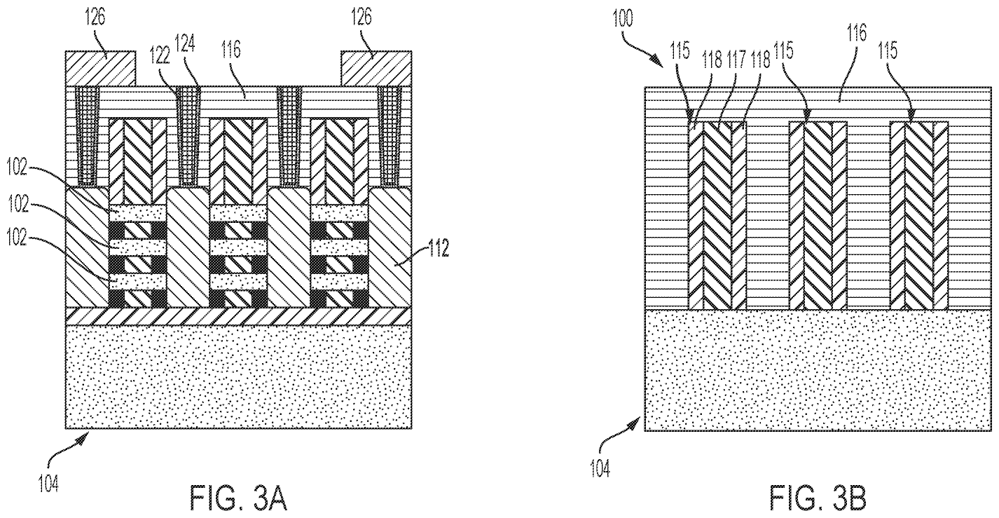

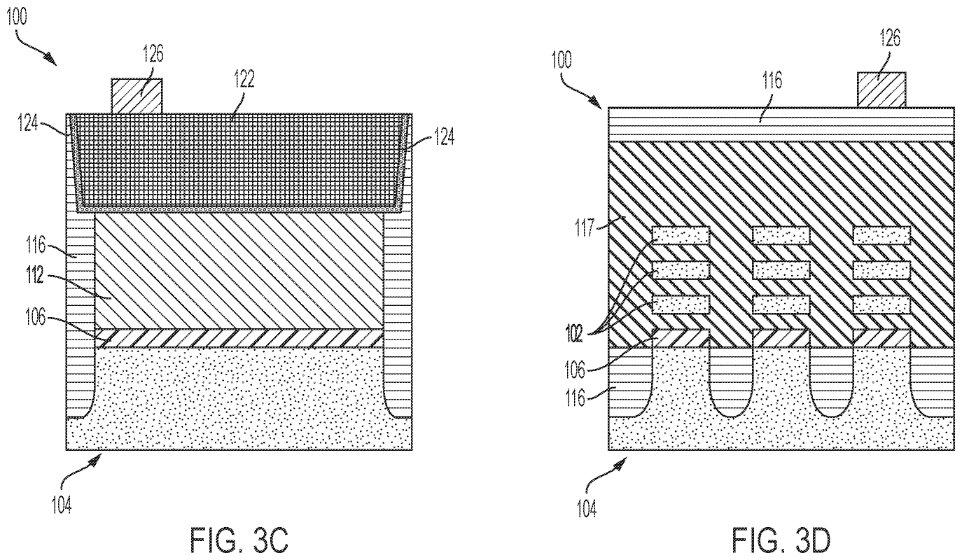

Turning now to FIGS. 3A-3D, the semiconductor device 100 is illustrated in various cross-sectional views following a source/drain contact mask patterning process. The source/drain contact mask patterning process involves depositing a mask material (e.g., silicon nitride (SiN)) on the upper surface of the ILD 116 and performing various masking, patterning and etching processes that are well-known to one of ordinary skill in the art. Accordingly, mask elements 126 are formed on the ILD upper surface and serve to protect targeted areas of the semiconductor device 100 (e.g., one or more targeted source/drain contacts 122) located beneath the mask elements 126 when performing one or more subsequent fabrication processes.

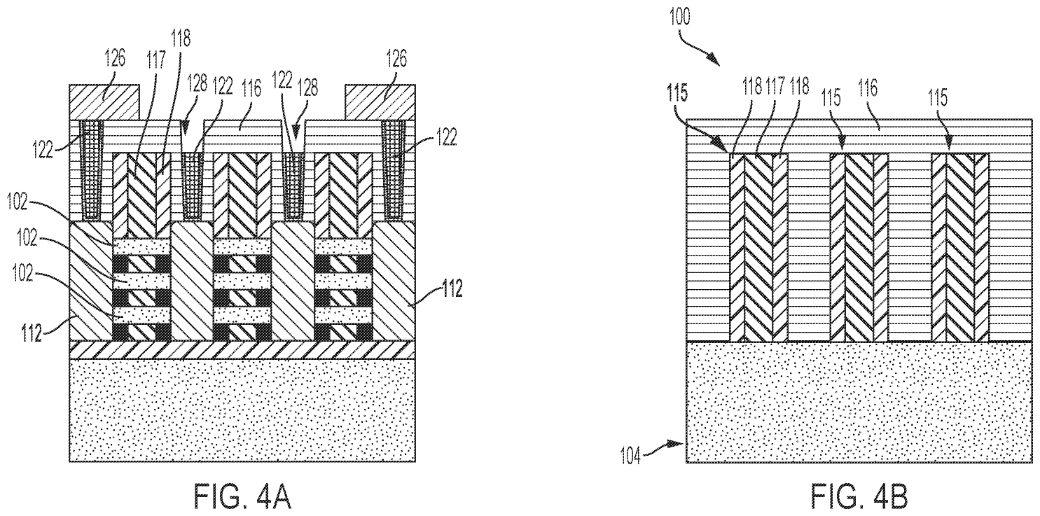

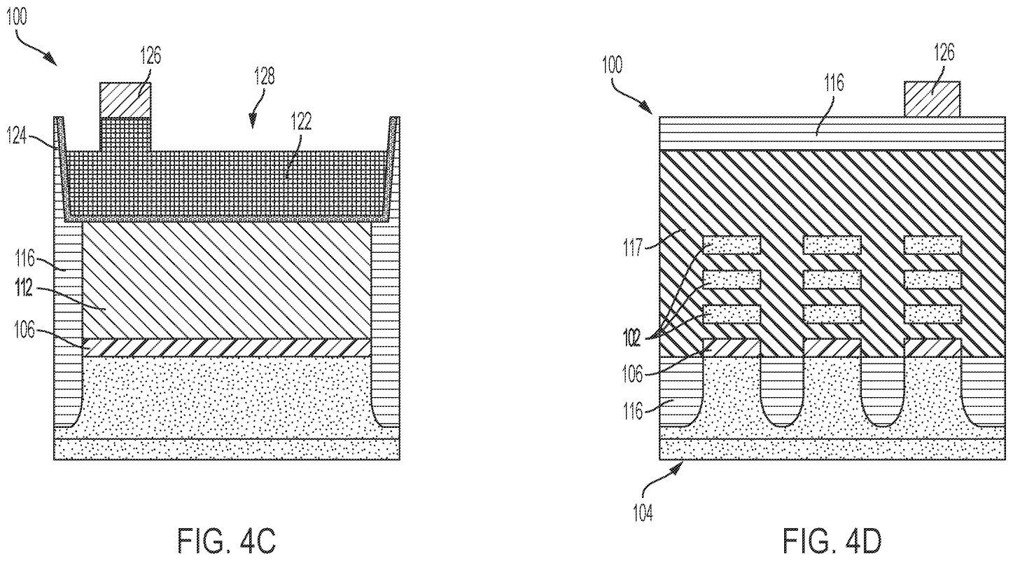

Referring to FIGS. 4A-4D, the semiconductor device 100 is illustrated in various cross-sectional views following a source/drain contact subtractive etch process (also referred to as a “subtractive patterning” process). Accordingly, the source/drain contact subtractive etch is selective to the mask elements 126 and the ILD 116. In this manner, the source/drain contacts 122 that are not covered by the mask elements 126 are partially recessed without etching or substantially etching the mask elements 126 or the ILD 116 to form corresponding ILD trenches 128. The source/drain contact subtractive etch process differs from a conventional damascene process in that rather than etching a cavity to define the profile of a contact and then subsequently filling the cavity with an electrically conductive material to establish the contact, the subtractive etch process according to one or more non-limiting embodiments of the invention involves recessing (e.g., “subtracting”) portions of the source/drain contacts 122 otherwise unprotected by the mask elements 126.

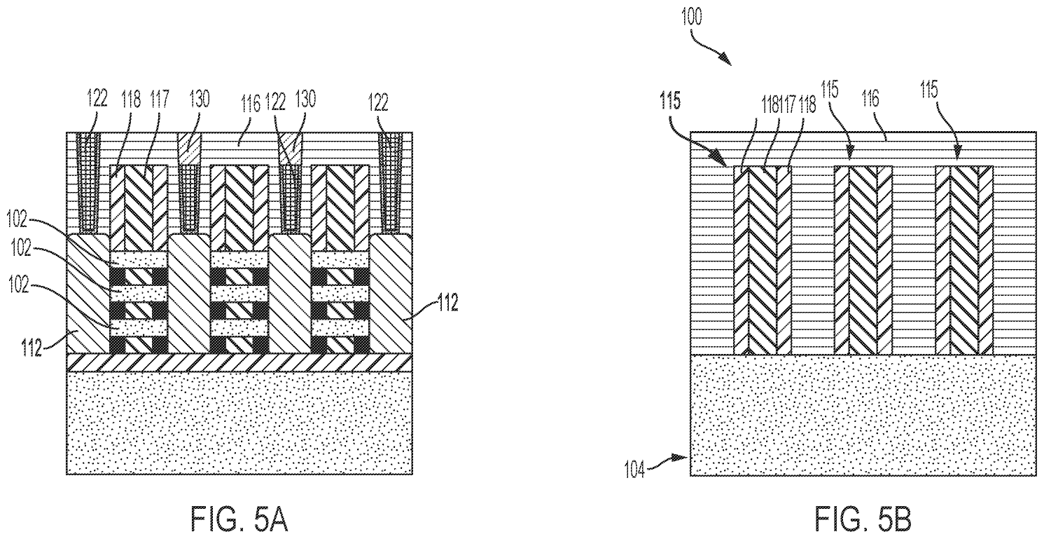

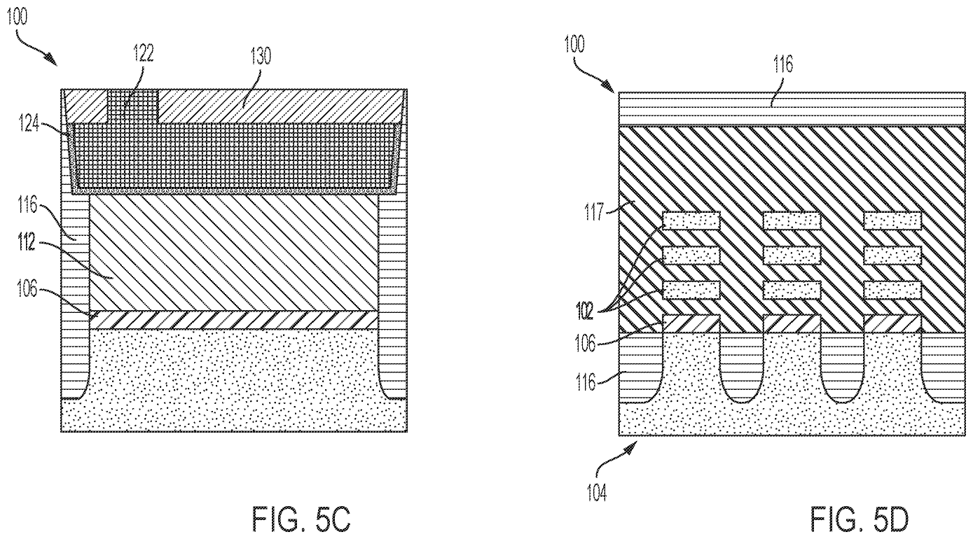

Referring to FIGS. 5A-5D, the semiconductor device 100 is illustrated in various cross-sectional views after performing a dielectric deposition process to fill the ILD trenches 128 with a dielectric material. The dielectric deposition process can include performing a chemical vapor deposition (CVD), a plasma-enhanced chemical vapor deposition (PECVD), or low-pressure chemical vapor deposition (LPCVD), for example, to fill the ILD trenches 128 with a dielectric material. The dielectric material can include, but is not limited to, silicon nitride (SiN), silicon carbon (SiC), aluminum oxide (AlOx), silicon oxide carbon (SiOC) and silicon oxide carbon nitride (SiOCN).

The resulting dielectric material that fills the ILD trenches 128 forms corresponding isolation elements 130. Each isolation element 130 separates the underlying recessed source/drain contacts 122 (i.e., the subtractive source/drain contacts) from the upper surface of the ILD 116. In this manner, the recessed source/drain contacts 122 can be electrically insulated from electrically conductive material deposited on the upper surface of the ILD trenches 128. In some embodiments, a metal layer (not shown) is formed on the semiconductor device 100 and extends across upper surfaces of the non-recessed source/drain contacts 122, the upper surface of the ILD 116, and the isolation elements 130. Accordingly, the non-recessed source/drain contacts 122 can be electrically connected (i.e., in electrical conductivity with one another), while the recessed source/drain contacts 122 are electrically isolated and disconnected from the non-recessed source/drain contacts 122.

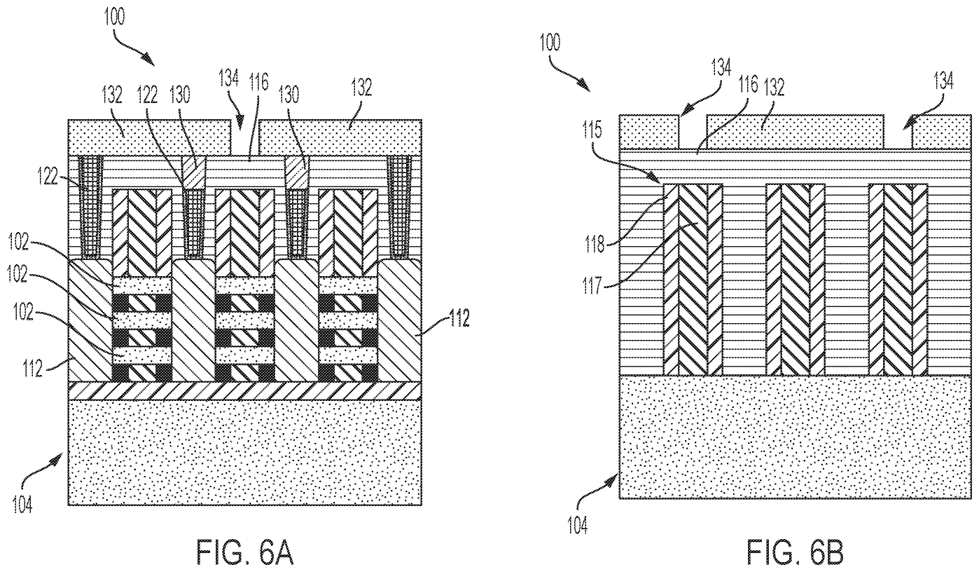

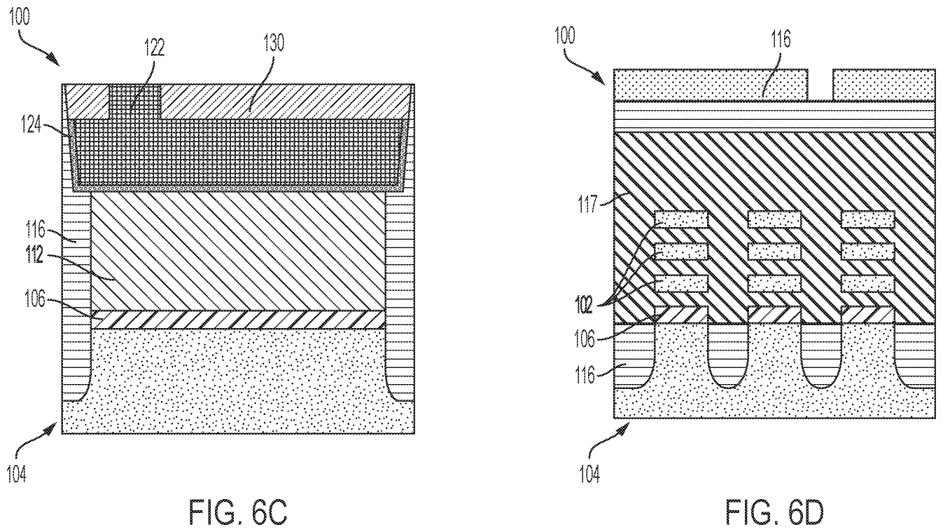

Turning to FIGS. 6A-6D, the semiconductor device 100 is illustrated in various cross-sectional views following a gate contact mask patterning process. The gate contact mask patterning process involves depositing a mask material (e.g., silicon nitride (SiN)) on the upper surface of the ILD 116 and performing various masking, patterning and etching processes that are well-known to one of ordinary skill in the art. Accordingly, masks 132 are formed on the ILD upper surface and serve to protect targeted areas of the semiconductor device 100 located beneath the masks 132 when performing one or more subsequent fabrication processes. The masks 132 are patterned to define mask openings 134 that are aligned with one or more targeted gate stacks 115 and expose the upper surface of the ILD 116.

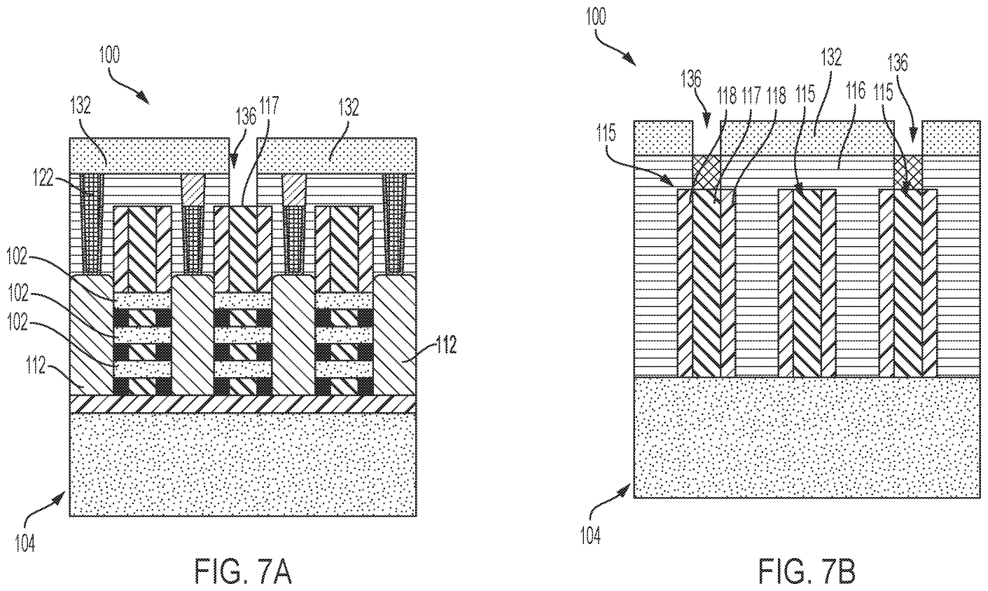

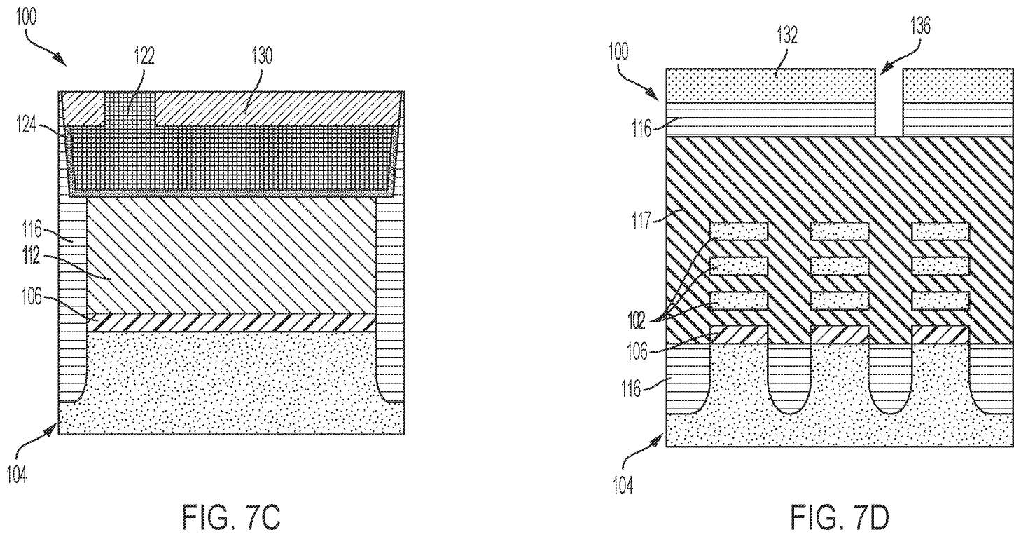

Referring now to FIGS. 7A-7D, the semiconductor device 100 is illustrated in various cross-sectional views following a gate contact etch process to form a gate contact trench 136 that exposes the underlying gate stack 115. In one or more non-limiting embodiments, the gate contact trenches 136 are formed by extending the patterned mask openings 134 into the ILD 116 using, for example, a reactive ion etch (RIE) process, while the masks 132 protect the underlying covered portions of the semiconductor device 100 from the RIE.

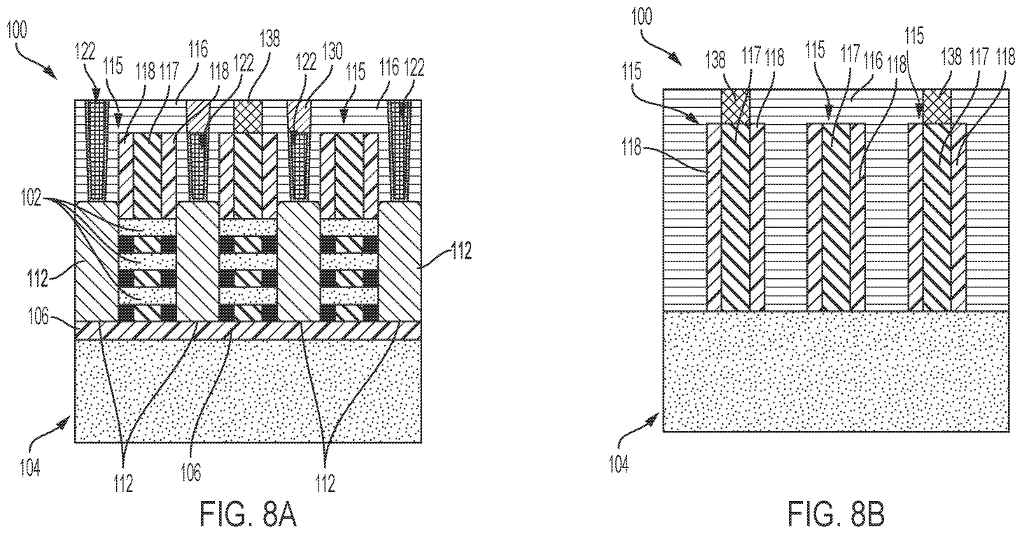

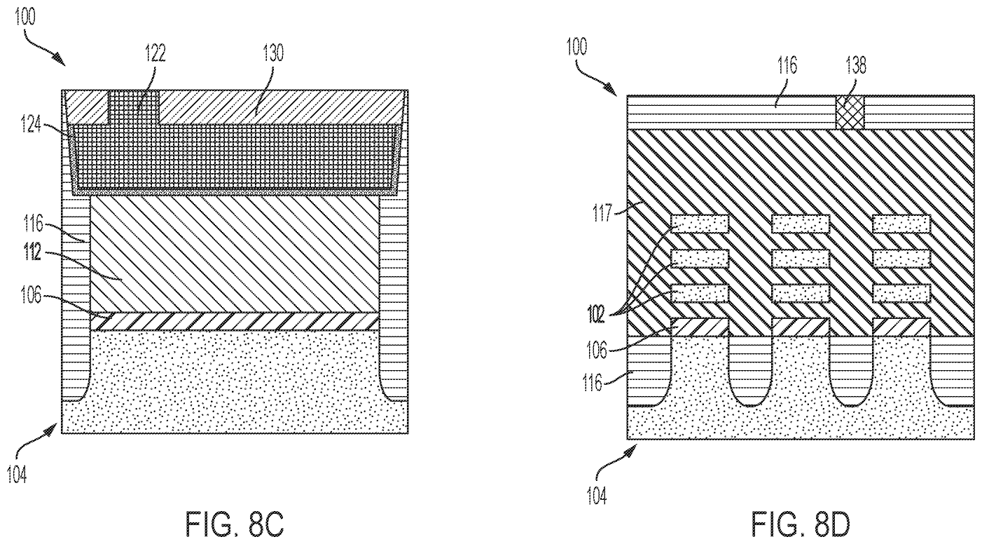

Turning to FIGS. 8A-8D, the semiconductor device 100 is illustrated in various cross-sectional views following a gate contact formation process to form an electrically conductive gate contact 138 on an upper surface of a respective gate stack 115. The gate contact formation process involves depositing an electrically conductive material in the gate contact trenches 136 and on an upper surface of the gate stack 115 (e.g., the gate electrode 117), and then planarizing the upper surface of the electrically conductive material and the ILD 116. Accordingly, the electrically conductive material remaining in the gate contact trench 136 defines the gate contact 138. According to one or more non-limiting embodiments, the gate contact 138 has a contact body that extends continuously from a bottom contact end that contacts the gate stack 115 (e.g., the gate electrode 117) to an upper contact end that is co-planar with an upper surface of the ILD 116.

The electrically conductive material can include, but is not limited to, copper (Cu), cobalt (Co), ruthenium (Ru), tungsten (W), and molybdenum (Mo). In one or more non-limiting embodiments, the electrically conductive material used to form the gate contact 138 is different from the electrically conductive material used to form the source/drain contacts 122. In other non-limiting embodiments, the electrically conductive material used to form the gate contact 138 is the as the electrically conductive material used to form the source/drain contacts 122. After filling the gate contact trenches 136 with the electrically conductive material a chemical-mechanical planarization (CMP) process, for example, can be performed to planarize the ILD upper surface. Accordingly, the electrically conductive material remaining in the gate contact trenches 136 defines an electrically conductive gate contact 138 which establishes electrical conductivity with the underlying gate stack 115.

According to one or more non-limiting embodiments of the invention, the gate contact formation process can involve performing a conformal deposition process to form a contact liner (not shown) on the sidewalls and the base of the gate contact trenches 136 prior to depositing the electrically conductive material used to establish the gate contact 138. The material used to form the liner can include, but is not limited to, titanium nitride (TiN), tantalum nitride (TaN), and tungsten (W).

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device comprises:
a first source/drain on an end of a first nanosheet stack a second source/drain on an end of a second nanosheet stack, and a third source/drain on an end of the first nanosheet stack or the second nanosheet stack;
an interlayer dielectric (ILD) covering the first and second nanosheet stacks, the first and second source/drains, and the first and second gate stacks; and
a first source/drain contact that contacts the first source/drain and a second source/drain contact that contacts the second source/drain, the first and second source/drain contacts extending continuously from the first and second source/drains, respectively, to an upper surface of the ILD;
a recessed source/drain contact that contacts the third source/drain; and
an isolation element separating the recessed source/drain contact from the upper surface of the ILD.

2. The semiconductor device of claim 1, further comprising a first gate stack wrapping around individual channels of the first nanosheet stack and a second gate stack wrapping around individual channels of the second nanosheet stack, wherein the ILD covers the first and second gate stacks.

3. The semiconductor device of claim 2, wherein each of the first and second source/drain contacts extends from an upper surface of the first and second source/drains, respectively, to an opposing upper end, and
wherein each of the first and second source/drain contacts excludes an interface between the bottom end and the upper end.

4. The semiconductor device of claim 3, further comprising at least one gate contact on at least one of the first and second gate stacks.

5. The semiconductor device of claim 4, wherein the at least one gate contact extends continuously from at least one of the first and second gate stacks to the upper surface of the ILD.

6. The semiconductor device of claim 5, wherein the isolation element is between the at least one gate contact and the first source/drain contact, or is between the at least one gate contact and the second source/drain contact.

7. A semiconductor device comprising:
a nanosheet stack between a first source/drain and a second source/drain;
a gate stack wrapping around individual channels of the nanosheet stack;
an interlayer dielectric (ILD) that covers the nanosheet stack, the first and second source/drains, and the gate stack;
a source/drain contact extending continuously from an upper surface of the first source/drain to an upper surface of the ILD;
a recessed source/drain contact on an upper surface of the second source/drain; and
an isolation element on an upper end of the recessed source/drain contact and separating the recessed source/drain contact from the upper surface of the ILD.

8. The semiconductor device of claim 7, wherein the source/drain contact extends from a bottom end that contacts the upper surface of the first source/drain to an opposing upper end that is co-planar with the upper surface of the ILD, and wherein the source/drain contact excludes an interface between the bottom end and the upper end.

9. The semiconductor device of claim 8, further comprising a gate contact on the gate stack.

10. The semiconductor device of claim 9, wherein the gate contact extends continuously from the gate stack to the upper surface of the ILD.

11. A method of fabricating a semiconductor device, the method comprising:
forming a plurality of nanosheet stacks above an upper surface of a semiconductor substrate;
forming a plurality of source/drains, each of the source/drains formed on an end of a respective nanosheet stack among the plurality of nanosheet stacks;
forming a plurality of gate stacks, each of the gate stacks wrapping around individual channels of a respective nanosheet stack among the plurality of nanosheet stacks;
depositing an interlayer dielectric (ILD) on the semiconductor substrate that covers the plurality of nanosheet stacks, the plurality of source/drains, and the plurality of gate stacks;
forming a plurality of source/drain contacts that contact the plurality of source/drains, each of the source/drain contacts extending continuously from the plurality of source/drains to an upper surface of the ILD;
recessing at least one of target source/drain contact among the plurality of source/drain contacts without recessing one or more remaining source/drain contacts among the plurality of source/drain contacts to form at least one ILD trench in the ILD; and
depositing a dielectric material in the at least one ILD trench to form at least one isolation element that separates the at least one target source/drain contact from the upper surface of the ILD.

12. The method of claim 11, wherein each of the one or more remaining source/drain contacts extends from a bottom end an opposing upper end, and
wherein each of the one or more remaining source/drain contacts excludes an interface between the bottom end and the upper end.

13. The method of claim 12, wherein forming the plurality of source/drain contacts comprises:
forming a plurality of source/drain contact trenches in the ILD, each of the source/drain contact trenches exposing a portion of a respective source/drain;
forming a contact liner on sidewalls of the source/drain contact trenches; and
depositing an electrically conductive material in the source/drain contact trenches to form the plurality of source/drain contacts.

14. The method of claim 13, wherein recessing the at least one of target source/drain contact comprises:
depositing a mask layer on the upper surface of the ILD;
patterning the mask layer to form mask elements that cover the one or more remaining source/drain contacts and define mask openings that expose that at least one target source/drain contact;
and performing a subtractive etch that partially recesses the at least one target source/drain contact and forms the at least one ILD trench.

15. The method of claim 12, wherein forming the at least one isolation element comprises:
forming a mask element over the one or more remaining source/drain contacts while exposing the at least one ILD trench; and
depositing a dielectric material in the at least one ILD trench and on an upper surface of the at least one target source/drain contact.

16. The method of claim 12, further comprising forming a gate contact on a respective gate stack among the plurality of gate stacks.

17. The method of claim 16, wherein forming the gate contact comprises:
forming a mask layer on the ILD;
patterning the mask layer to form mask elements that cover the at least one target source/drain contact and the one or more remaining source/drain contacts and to define a mask opening that exposes a portion of the ILD;
etching the exposed portion of the ILD to form a gate contact trench that exposes the respective gate stack; and
depositing an electrically conductive material in the gate contact trench to form the gate contact.

18. The method of claim 17, wherein the gate contact has a contact body that extends continuously from the respective gate stack to the upper surface of the ILD.

19. The method of claim 18, wherein the gate contact is formed between a first isolation element on a first target source/drain contact and a second isolation element on a second target source/drain contact.

20. The method of claim 19, wherein the first isolation element and the second isolation element electrically isolate the first and second target source/drain contacts from the one or more remaining source/drain contacts.
